(19) United States
(12) Patent Application Publication
(10) Pub. No.: US 2006/0199086 A1
(43) Pub. Date: Sep. 7, 2006

(54) System and method for creating a color filter for a display panel

(76) Inventors: Philip S. Burkum, Corvallis, OR (US); Ravi Prasad, Corvallis, OR (US); Lawrence R. Plotkin, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/072,032

(22) Filed: Mar. 4, 2005

(51) Int. Cl. G03F 9/00

(52) U.S. Cl. 430/7

(57) ABSTRACT

A system for generating a color filter for a display panel is provided. The system comprises a photoconductor drum, a first liquid toner cartridge configured to transfer first liquid toner to a first discharged portion of the photoconductor drum to form a first image on the photoconductor drum, a cylindrical intermediate transfer member configured to receive the image from the photoconductor drum, and an impression mechanism configured to drive a substrate along the cylindrical intermediate transfer member to cause the first image to be transferred to the substrate.

### BACKGROUND

Liquid crystal display (LCD) devices may be found in many electric devices. LCD devices include a screen with pixels that are configured to transmit or not transmit light according to an image input to form an image. Among other factors, the resolution of the image depends on the size of the pixels. Generally speaking, smaller pixels may be used to generate an image with a higher resolution than larger pixels. Accordingly, it is often desirable to produce LCD devices with as small of a pixel size as possible.

LCD devices typically include liquid crystal material contained between a pair of display panels. One of the display panels often includes the electronics to cause the liquid crystal material to transmit or not transmit light for each pixel, and the other display panel often includes a color filter to allow color to be produced by a pixel when it transmits light. The color filter may include optical layers such as a black matrix layer, one or more color filter layers, a planarization layer, and a dielectric layer. In producing a display panel with a color filter, it is generally desirable to generate the color filter as small as possible while maintaining the precision of the optical layers therein.

### SUMMARY

One form of the present invention provides a system for generating a color filter for a display panel. The system comprises a photoconductor drum, a first liquid toner cartridge configured to transfer first liquid toner to a first discharged portion of the photoconductor drum to form a first image on the photoconductor drum, a cylindrical intermediate transfer member configured to receive the image from the photoconductor drum, and an impression mechanism configured to drive a substrate along the intermediate transfer member to cause the first image to be transferred to the substrate.

### BRIEF DESCRIPTION OF THE DRAWINGS

FIG. 1 is a schematic diagram illustrating a system for generating and transferring layers to a substrate using a liquid electrophotography process according to one embodiment of the present invention.

FIG. 2A is a schematic diagram illustrating an impression mechanism according to one embodiment of the present invention.

FIG. 2B is a schematic diagram illustrating an impression mechanism according to one embodiment of the present invention.

FIG. 3 is a flow chart illustrating a method for generating and transferring layers to a substrate using a liquid electrophotography process according to one embodiment of the present invention.

FIG. 4 is a flow chart illustrating a method for generating and transferring layers to a substrate with a blanket using a liquid electrophotography process according to one embodiment of the present invention.

FIG. 5 is a flow chart illustrating a method for generating and transferring layers of a display panel to a substrate using a liquid electrophotography process according to one embodiment of the present invention.

FIG. 6 is a schematic diagram illustrating layers transferred to a blanket as part of a liquid electrophotography process according to one embodiment of the present invention.

FIG. 7A is a schematic diagram illustrating a first perspective of layers transferred to a display panel using a liquid electrophotography process according to one embodiment of the present invention.

FIG. 7B is a schematic diagram illustrating a second perspective of layers transferred to a display panel using a liquid electrophotography process according to one embodiment of the present invention.

FIG. 8 is a schematic diagram illustrating a liquid crystal display (LCD) device according to one embodiment of the present invention.

### DETAILED DESCRIPTION

In the following detailed description of the preferred embodiments, reference is made to the accompanying drawings, which form a part hereof, and in which is shown by way of illustration specific embodiments in which the invention may be practiced. It is to be understood that other embodiments may be utilized and structural or logical changes may be made without departing from the scope of the present invention. The following detailed description, therefore, is not to be taken in a limiting sense, and the scope of the present invention is defined by the appended claims.

As described herein, a system and method for creating layers on a front panel of a liquid crystal display (LCD) using a liquid electrophotography (LEP) process is provided. The layers may include one or more color filter layers, a black matrix layer, a planarization layer, and a dielectric layer, for example. Using the system and method, each layer is generated on a photoconductor drum and transferred to an intermediate transfer medium such as a blanket. The combined layers on the intermediate transfer medium are transferred to a substrate that comprises the front panel of a liquid crystal display (LCD).

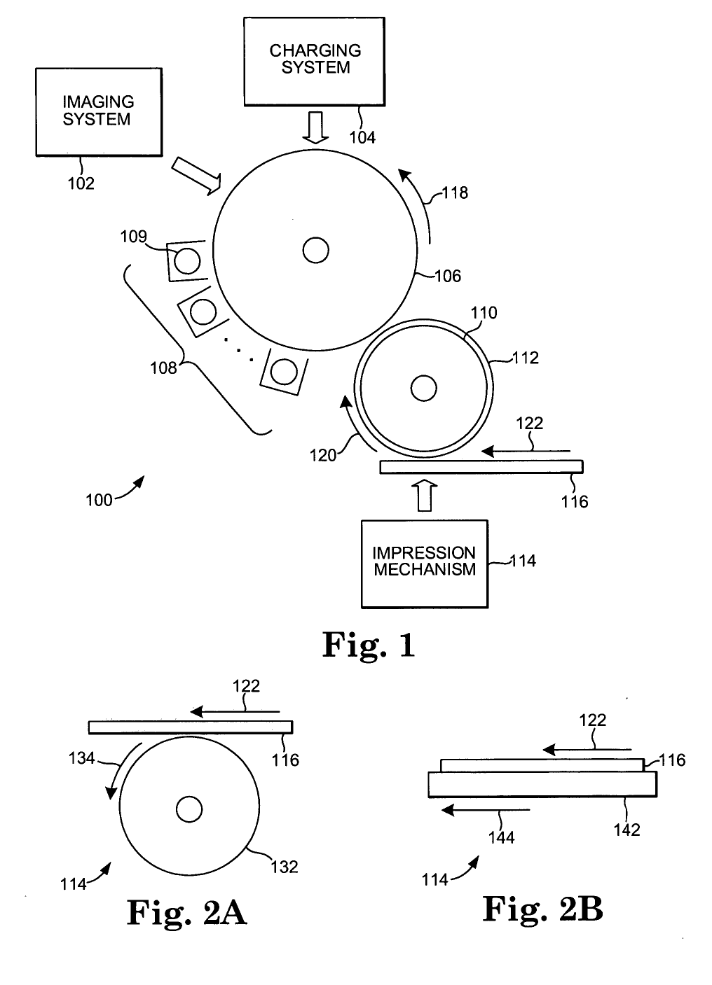

FIG. 1 is a schematic diagram illustrating a system 100 for generating and transferring layers to a substrate 116 using a liquid electrophotography process. System 100 includes an imaging system 102, a charging system 104, a cylindrical photoconductor drum 106, a plurality of liquid toner cartridges 108, a cylindrical intermediate transfer member 110 that includes a blanket 112, and an impression mechanism 114.

Imaging system 102 is a laser imager configured to create a latent image on photoconductor drum 106. Charging system 104 includes a scorotron assembly (not shown) that includes one or more scorotron units (not shown). The scorotron units are configured to negatively charge photoconductor drum 106 as photoconductor drum 106 is rotated past charging system 104 as indicated by an arrow 118. Image system 102 includes at least one writing head configured to project a laser beam onto selected areas of photoconductor drum 106 to discharge the selected areas as photoconductor drum 106 is rotated past imaging system 102. The discharged areas of photoconductor drum 106 comprise the latent image.

Each of the liquid toner cartridges 108 includes a developer 109 and liquid toner of a selected type, e.g., black matrix, color filter, planarization, or dielectric, and color, e.g., red, green, blue, or black. The liquid toner comprises particles that have been milled into a pigmented plastic and dissolved into Isopar™, i.e., an Isoparaffinic solvent available from ExxonMobil Chemical Company, 13501 Katy Freeway, Houston, Tex. 77079 USA, along with a charge director. In one embodiment, one liquid toner cartridge 108 includes a black pigment that is used to create a black matrix layer. Three liquid toner cartridges 108 include red, green, and blue pigments, respectively, that are used to create color filter layers. One liquid toner cartridge 108 includes a transparent material that is used to create a planarization layer, and one liquid toner cartridge 108 includes a dielectric material that is used to create a dielectric layer. In other embodiments, system 100 includes other types or numbers of liquid toner cartridges 108.

In response to being activated, a liquid toner cartridge 108 develops the liquid toner using developer 109. As the discharged areas of photoconductor drum 106 pass over an activated liquid toner cartridge 108, liquid toner transfers from developer 109 in activated liquid toner cartridge 108 to the discharged areas of photoconductor drum 106 to create an image.

The image is transferred electrostatically from photoconductor drum 106 to blanket 112 as photoconductor drum 106 rotates past intermediate transfer member 110. Intermediate transfer member 110 rotates in the direction indicated by arrow 120. In one embodiment, blanket 112 comprises a multi-layer fabric-reinforced foam rubber configured to electrostatically transfer the liquid toner from photoconductor drum 106 to intermediate transfer member 110. In other embodiments, blanket 112 comprises another type of material. Intermediate transfer member 110 heats the image on blanket 112 to cause the Isopar in the image to evaporate. Blanket 112 also absorbs some of the Isopar in the image to increase the solid content of the image.

A discharge system (not shown) such as a light emitting diode (LED) erase lamp removes residual charge from photoconductor drum 106 prior to the image being transferred to blanket 112. After the image is transferred to blanket 112, a cleaning system (not shown) cleans photoconductor drum 106 to remove any remaining toner.

System 100 repeats the above process to create any number of additional layers of images on blanket 112. The additional layers may be the same type and/or color, i.e. use liquid toner from the same liquid toner cartridge 108, or may be a different type and/or color, i.e. use liquid toner from a different liquid toner cartridge 108 as any previous layers.

After all of the layers have been created on blanket 112, the combined image is transferred from blanket 112 to substrate 116 using impression mechanism 114. Impression mechanism 114 drives substrate 116 along intermediate transfer member 110 in the direction indicated by an arrow 122 and applies pressure to substrate 116 to cause the combined image, i.e. all layers created on blanket 112, to be transferred to substrate 116. The combination of substrate 116 and the layers transferred to substrate 116 are referred to herein as display panel 116. Substrate 116 comprises any material suitable for use as a display panel for a LCD device such as glass or clear plastic.

FIG. 2A is a schematic diagram illustrating an embodiment of impression mechanism 114. In FIG. 2A, impression mechanism 114 comprises an impression cylinder 132 that rotates in the direction indicated by an arrow 134 to drive substrate 116 between intermediate transfer member 110 (shown in FIG. 1) and impression cylinder 132 in the direction indicated by arrow 122. As substrate 116 passes between intermediate transfer member 110 and impression cylinder 132, impression cylinder 132 also applies pressure between substrate 116 and intermediate transfer member 110 to cause the combined image, i.e. all layers created on blanket 112, to be transferred to substrate 116.

FIG. 2B is a schematic diagram illustrating another embodiment of impression mechanism 114. In FIG. 2B, impression mechanism 114 comprises a platen 142 that is driven in the direction indicated by an arrow 144 to drive substrate 116 between intermediate transfer member 110 (shown in FIG. 1) and platen 142 in the direction indicated by arrow 122. As substrate 116 passes between intermediate transfer member 110 and platen 142, platen 142 also applies pressure between substrate 116 and intermediate transfer member 110 to cause the combined image, i.e. all layers created on blanket 112, to be transferred to substrate 116.

In other embodiments, photoconductor drum 106 includes a permanent pattern that comprises the latent image. In those embodiment, imaging system 102 may be omitted.

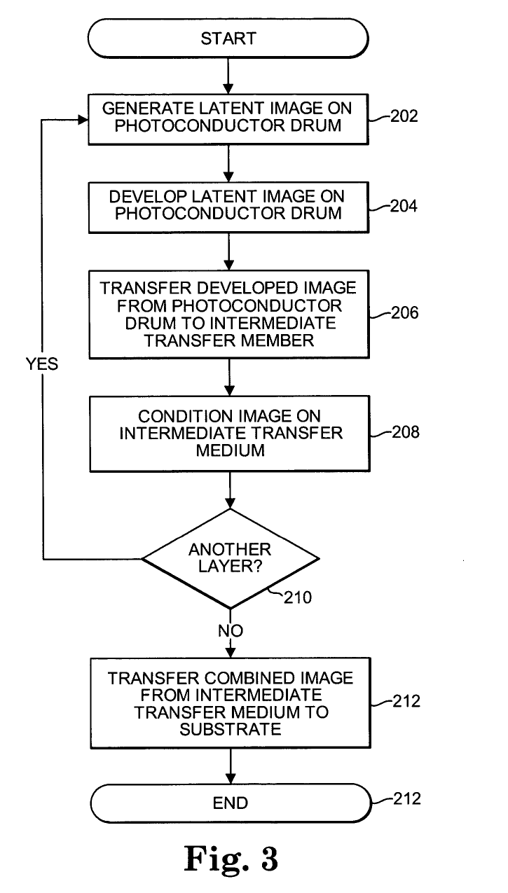

FIG. 3 is a flow chart illustrating a method for generating and transferring layers to a substrate using a liquid electrophotography process. The method of FIG. 3 will be described with reference to system 100.

In FIG. 3, a latent image is generated on photoconductor drum 106 as indicated in a block 202. In system 100, imaging system 102 discharges selected areas of photoconductor drum 106 that have been negatively charged by charging system 104 to generate the latent image. The latent image is developed on photoconductor drum 106 as indicated in a block 204. An activated liquid toner cartridge 108 applies liquid toner to the discharged areas of photoconductor drum 106 to develop the latent image.

The developed image is transferred from photoconductor drum 106 to intermediate transfer member 110 as indicated in a block 206. To transfer the developed image from photoconductor drum 106 to intermediate transfer member 110, an electrical bias is applied to blanket 112 to cause the charged liquid toner that comprises the developed image to transfer to blanket 112 on intermediate transfer member 110.

The image is conditioned on intermediate transfer member 110 as indicated in a block 208. Intermediate transfer member 110 heats blanket 112 to cause the Isopar in the liquid toner to evaporate and the plastic-coated particles in the liquid toner to form a film to condition the image. By evaporating the Isopar, the liquid toner solidifies on blanket 112.

A determination is made as to whether there is another layer to generate as indicated in a block 210. If there is another layer to generate, then the process of blocks 202 through 208 is repeated for the next layer. The next layer may be generated using liquid toner from the same or a different liquid toner cartridge 108 as the previous layer.

If there is not another layer to generate, then the combined image, i.e. the images from each layer generated in the process of blocks 202 through 210, is transferred from intermediate transfer member 110 to substrate 116 as indicated in a block 212. Impression mechanism 114 drives substrate 116 between intermediate transfer member 110 and impression mechanism 114 and applies pressure between substrate 116 and intermediate transfer member 110 to cause the combined image to be transferred to substrate 116.

In one embodiment of the method of FIG. 3, the optical layers generated and transferred to substrate 116 include a black matrix layer, a color filter layer, a planarization layer, and a dielectric layer. Each layer may be created using one or more than one iteration of the functions shown in blocks 202 through 208. In other embodiments, more or fewer layers may be generated and transferred to substrate 116.

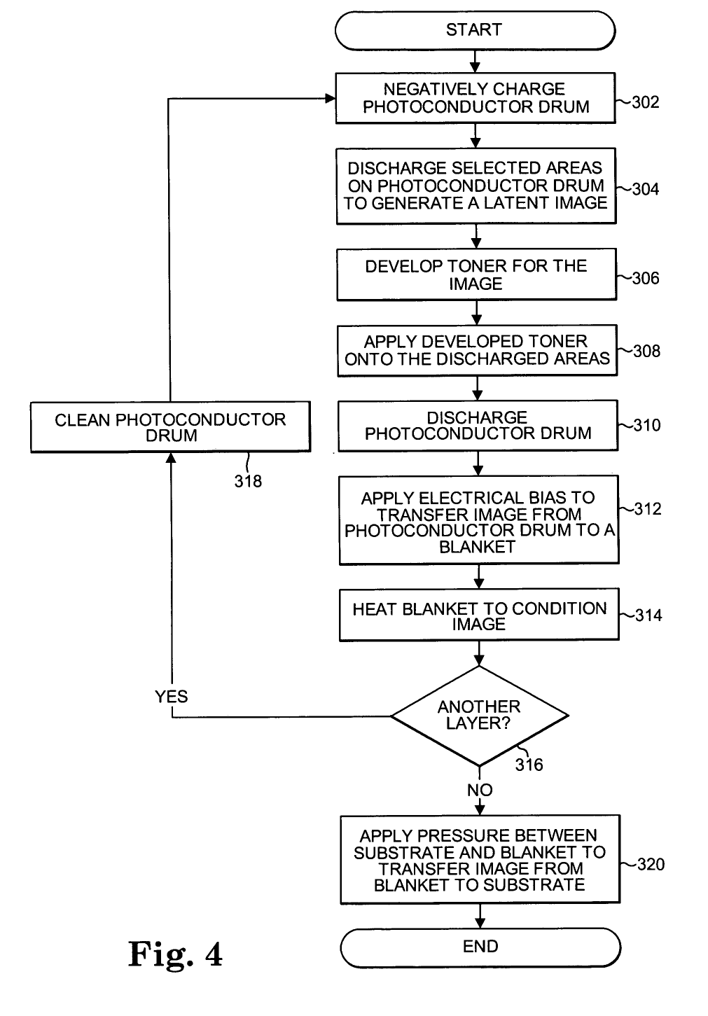

FIG. 4 is a flow chart illustrating a method for generating and transferring layers to a substrate with a blanket using a liquid electrophotography process. The method of FIG. 4 will be described with reference to system 100.

In FIG. 4, charging system 104 negatively charges photoconductor drum 106 as indicated in a block 302. Imaging system 102 discharges selected areas on photoconductor drum 106 to generate a latent image on photoconductor drum 106 as indicated in a block 304. A liquid toner cartridge 108 is activated to develop toner for the image as indicated in a block 306. The activated liquid toner cartridge 108 applies developed toner to the discharged areas of photoconductor drum 106 to develop the latent image as indicated in a block 308. A discharging system (not shown) discharges photoconductor drum 106 as indicated in a block 310.

An electrical bias is applies to intermediate transfer member 110 to transfer the image from photoconductor drum 106 to blanket 112 as indicated in a block 312. Intermediate transfer member 110 heats blanket 112 to condition the image by causing the Isopar in the liquid toner to evaporate and the plastic-coated particles in the liquid toner to form a film as indicated in a block 314.

A determination is made as to whether there is another layer to generate as indicated in a block 316. If there is another layer to generate, then photoconductor drum 106 is cleaned to remove any remaining toner as indicated in a block 318 and the process of blocks 302 through 314 is repeated for the next layer. The next layer may be generated using liquid toner from the same or a different liquid toner cartridge 108 as the previous layer.

If there is not another layer to generate, then impression mechanism 114 applies pressure between substrate 116 and intermediate transfer member 110 to cause the combined image to be transferred from blanket 112 to substrate 116 as impression mechanism 114 drives substrate 116 between intermediate transfer member 110 and impression mechanism 114 as indicated in a block 320.

In one embodiment of the method of FIG. 4, the optical layers generated and transferred to substrate 116 include a black matrix layer, a color filter layer, a planarization layer, and a dielectric layer. Each layer may be created using one or more than one iteration of the functions shown in blocks 202 through 208. In other embodiments, more or fewer layers may be generated and transferred to substrate 116.

FIG. 5 is a flow chart illustrating a method for generating and transferring optical layers of a display panel to substrate 116 using a liquid electrophotography process as described above with reference to the embodiments of FIGS. 2 and 3. In particular, each layer in the embodiment of FIG. 5 is created using either substantially the functions of blocks 202 through 208 of FIG. 3 or substantially the functions of blocks 302 through 314 and 318 of FIG. 4. The creation of each layer may involve one or more iterations of the functions of blocks 202 through 208 of FIG. 3 or the functions of blocks 302 through 314 and 318 of FIG. 4.

In FIG. 5, a black matrix layer is created on blanket 112 as indicated in a block 400. Color filter layers are created on blanket 112 as indicated in a block 402. A planarization layer is created on blanket 112 as indicated in a block 404. A dielectric layer is created on blanket 112 as indicated in a block 406. The optical layers, including the black matrix, color filter, planarization, and dielectric layers, are simultaneously transferred to substrate 116 as indicated in a block 408 and collectively comprise a color filter.

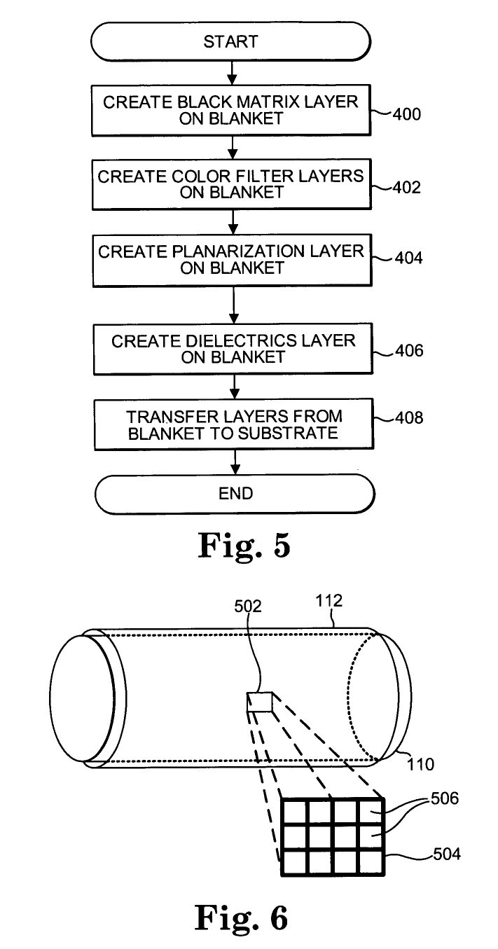

FIG. 6 is a schematic diagram illustrating layers transferred to blanket 112 as part of a liquid electrophotography process as described above with reference to the embodiments of FIGS. 1 through 4. As shown in a selected portion 502 of blanket 112, the layers created on blanket 112 include a black matrix layer 504 and color filter layers 506 interspersed in black matrix layer 504. The layers also include at least a planarization layer (not shown) and a dielectric layer (not shown). Other embodiments include patterns of black matrix layer 504 other than the pattern shown in FIG. 6.

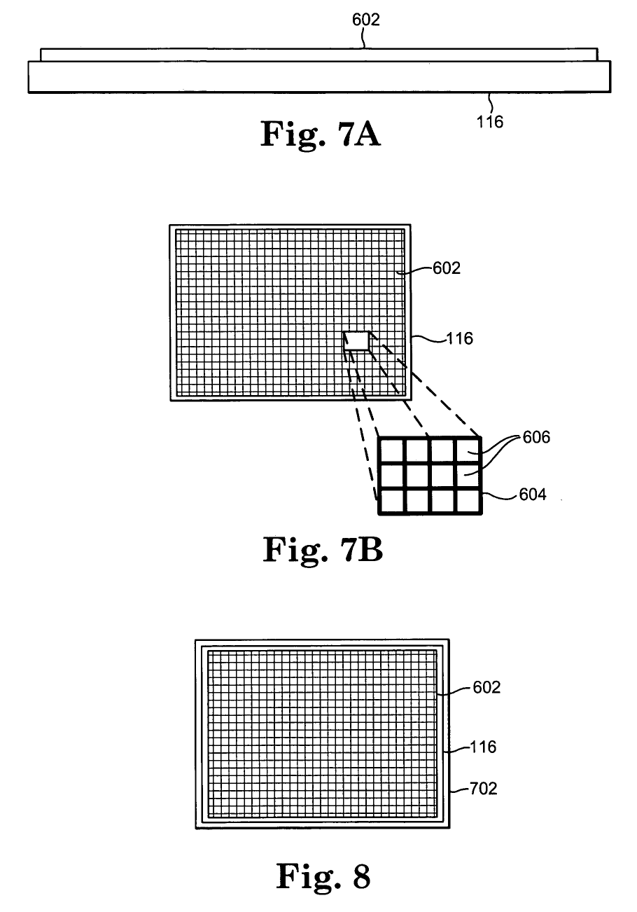

FIGS. 7A and 7B are schematic diagrams illustrating first and second perspectives of a color filter 602 transferred to display panel 116 using a liquid electrophotography process as described above with reference to the embodiments of FIGS. 1 through 4. FIG. 7A illustrates a side view showing color filter 602 on display panel 116. FIG. 7B illustrates a top view where an expanded portion shows a black matrix layer 604 and color filter layers 606 interspersed in black matrix layer 604. Other embodiments include patterns of black matrix layer 604 other than the pattern shown in FIG. 7B.

FIG. 8 is a schematic diagram illustrating a liquid crystal display (LCD) device 702. LCD device 702 includes display panel 116 and other components that are configured to display still or video images. The other components may include a rear panel (not shown) that is combined with display panel 116 to house liquid crystal material. The rear panel may include a transistor or diode and conductive interconnect lines for each pixel formed in display panel 116. Each transistor or diode is operated to cause an associated pixel in display panel 116 to transmit or not transmit light according to an image to be displayed.

LCD device 702 comprises any type of LCD device such as a flat screen or rear projection television, a personal computer system display, a laptop or notebook computer system display, or a video or image display system, for example.

Although specific embodiments have been illustrated and described herein for purposes of description of the preferred embodiment, it will be appreciated by those of ordinary skill in the art that a wide variety of alternate and/or equivalent implementations may be substituted for the specific embodiments shown and described without departing from the scope of the present invention. Those with skill in the mechanical, electromechanical, electrical, and computer arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

What is claimed is:

1. An apparatus for generating a color filter for a display panel, the system comprising:
a photoconductor drum;
a first liquid toner cartridge configured to transfer first liquid toner to a first discharged portion of the photoconductor drum to form a first image on the photoconductor drum;
a cylindrical intermediate transfer member configured to receive the image from the photoconductor drum; and
an impression mechanism configured to drive the display panel along the cylindrical intermediate transfer member to cause the first image to be transferred to the display panel.

2. The apparatus of claim 1 further comprising:
a charging system configured to charge the photoconductor drum; and
an imaging system configured to create the first discharged portion of the photoconductor drum.

3. The apparatus of claim 1 wherein the cylindrical intermediate transfer member includes a blanket configured to receive the first image from the photoconductor drum.

4. The apparatus of claim 3 wherein the cylindrical intermediate transfer member is configured to heat the blanket.

5. The apparatus of claim 1 wherein the first liquid toner cartridge is configured to transfer the first liquid toner to a second discharged portion of the photoconductor drum to form a second image on the photoconductor drum subsequent to the first image being transferred to the intermediate transfer member.

6. The apparatus of claim 1 further comprising:
a second liquid toner cartridge configured to transfer second liquid toner to a second discharged portion of the photoconductor drum to form a second image on the photoconductor drum.

7. The apparatus of claim 6 wherein the second liquid toner cartridge configured to transfer the second liquid toner to the second discharged portion of the photoconductor drum to form the second image on the photoconductor drum prior to the first image being transferred to the display panel.

8. The apparatus of claim 1 wherein the impression mechanism is configured to apply pressure between the display panel and the cylindrical intermediate transfer member to cause the image to be transferred to the display panel.

9. The apparatus of claim 1 wherein the impression mechanism comprises an impression cylinder.

10. The apparatus of claim 1 wherein the impression mechanism comprises a platen.

11. The apparatus of claim 1 wherein the display panel comprises a glass panel.

12. The apparatus of claim 1 wherein the display panel comprises a clear plastic panel.

13. The apparatus of claim 1 wherein the image comprises a black matrix layer.

14. The apparatus of claim 1 wherein the image comprises a color filter layer.

15. The apparatus of claim 1 wherein the image comprises a planarization layer.

16. The apparatus of claim 1 wherein the image comprises a dielectric layer.

17. A system comprising:
means for generating a first image on a photoconductor drum;
means for developing the first image on the photoconductor drum using a first liquid toner cartridge;
means for transferring the first image from the photoconductor drum to a cylindrical intermediate transfer member; and
means for transferring the first image from the cylindrical intermediate transfer member to a display panel.

18. The system of claim 17 further comprising:
means for charging the photoconductor drum; and
means for creating the first discharged portion of the photoconductor drum.

19. The system of claim 17 further comprising:
means for heating the cylindrical intermediate transfer member.

20. The system of claim 17 further comprising:
means for applying pressure between the display panel and the cylindrical intermediate transfer member to cause the image to be transferred to the display panel.

21. The system of claim 17 further comprising:
means for generating a second image on the photoconductor drum;
means for developing the second image on the photoconductor drum using a second liquid toner cartridge;
means for transferring the second image from the photoconductor drum to the cylindrical intermediate transfer member; and
means for transferring the second image from the cylindrical intermediate transfer member to the display panel.

22. The system of claim 21 wherein the second image is transferred from the photoconductor drum to the cylindrical intermediate transfer member prior to the first image being transferred from the cylindrical intermediate transfer member to the display panel.

23. A method of generating a color filter for a display panel, the method comprising:
generating a first image on a photoconductor drum;
developing the first image on the photoconductor drum using a first liquid toner cartridge;
transferring the first image from the photoconductor drum to a cylindrical intermediate transfer member; and
transferring the first image from the cylindrical intermediate transfer member to the display panel.

24. The method of claim 23 further comprising:
conditioning the first image on the cylindrical intermediate transfer member prior to transferring the first image from the cylindrical intermediate transfer member to the display panel.

25. The method of claim 23 further comprising:
generating a second image on the photoconductor drum;
developing the second image on the photoconductor drum using a second liquid toner cartridge;
transferring the second image from the photoconductor drum to the cylindrical intermediate transfer member; and
transferring the second image from the cylindrical intermediate transfer member to the display panel.

26. The method of claim 25 further comprising:
transferring the second image from the photoconductor drum to the cylindrical intermediate transfer member prior to transferring the first image from the cylindrical intermediate transfer member to the display panel.

27. The method of claim 23 further comprising:
charging the photoconductor drum; and
discharging a portion of the photoconductor drum to generate the first image.

28. The method of claim 23 wherein the display panel comprises a glass panel.

29. A method comprising:
creating a black matrix layer on a blanket on a cylindrical intermediate transfer member;
creating a plurality of color filter layers on the blanket on the cylindrical intermediate transfer member; and
transferring the black matrix layer and the plurality of color filter layers from the blanket to a substrate.

30. The method of claim 29 further comprising:
creating the black matrix layer on a photoconductor drum;
creating the plurality of color filter layers on the photoconductor drum; and
transferring the black matrix layer and the plurality of color filter layers from the photoconductor drum to the blanket.

31. The method of claim 29 further comprising:
creating a planarization layer on the blanket on the cylindrical intermediate transfer member; and
transferring the planarization layer from the blanket to a substrate.

32. The method of claim 29 further comprising:
creating a dielectric layer on the blanket on the cylindrical intermediate transfer member; and
transferring the dielectric layer from the blanket to a substrate.

33. A liquid crystal display that includes a display panel with a color filter generated by:
generating an image on a photoconductor drum;
developing the image on the photoconductor drum using a liquid toner cartridge;
transferring the image from the photoconductor drum to a cylindrical intermediate transfer member; and
transferring the image from the cylindrical intermediate transfer member to the display panel.
